(19) United States
(12) Patent Application Publication
(10) Pub. No.: US 2006/0172478 A1
(43) Pub. Date: Aug. 3, 2006

(54) Method for manufacturing integrated circuit having at least one silicon-germanium heterobipolar transistor

(75) Inventor: Peter Brandl, Villach (AT)

Correspondence Address: MCGRATH, GEISSLER, OLDS & RICHARDSON, PLLC, P.O. BOX 1364, FAIRFAX, VA, 22038-1364, US

(73) Assignee: ATMEL GERMANY GMBH

(21) Appl. No.: 11/344,090

(22) Filed: Feb. 1, 2006

(30) Foreign Application Priority Data
Feb. 2, 2005 (DE) DE 102005004708

(51) Int. Cl. H01L 21/8234

(52) U.S. Cl. 438/197

(57) ABSTRACT

A method for manufacturing integrated circuits having at least one silicon-germanium heterobipolar transistor is provided, wherein a dielectric applied to the surface of the wafer is planarized. The dielectric having elevations produced by the thickness of monocrystalline semiconductor regions structured below the dielectric, wherein the semiconductor regions are covered by a first stop layer, in that for the purpose of planarization, a second stop layer is applied to the dielectric. Subsequently, a planarization layer, which in the area of each elevation forms a smaller layer thickness than outside the area of each elevation, is applied to the second stop layer. Thereafter, the planarization layer is removed in the area of each elevation and the second stop layer is removed in the area of each elevation. Then, the wafer is polished chemically-mechanically in such a way that the dielectric in the area of each elevation is made thinner at least up to the first stop layer.

This nonprovisional application claims priority under 35 U.S.C. § 119(a) on German Patent Application No. DE 102005004708, which was filed in Germany on Feb. 2, 2005, and which is herein incorporated by reference.

### BACKGROUND OF THE INVENTION

1. Field of the Invention

The present invention relates to a method for manufacturing integrated circuits having at least one silicon-germanium heterobipolar transistor.

2. Description of the Background Art

Semiconductor circuits and methods for manufacturing the same, which have heterobipolar transistors with a silicon-germanium mixed crystal in the base semiconductor region, are known from the state of the art.

### SUMMARY OF THE INVENTION

It is an object of the present invention to provide a method for manufacturing integrated circuits.

According to an embodiment of the present invention, a dielectric applied to the surface of the wafer is planarized. The wafer is preferably a monocrystalline silicon wafer having, for example, a lattice orientation of <100>. The dielectric is, for example, silicon dioxide (SiO₂), the invention also includes other planarizable dielectrics. The dielectric made of silicon dioxide may also be called a field oxide in its later function.

The dielectric has elevations, produced by the thickness of monocrystalline semiconductor regions structured below the dielectric. These monocrystalline semiconductor regions can be, for example, epitaxially applied collector semiconductor regions of high-frequency bipolar transistors. In addition to the monocrystalline semiconductor regions, other structural unevennesses below the dielectric may also lead to the formation of elevations. The monocrystalline semiconductor regions can be covered by a first stop layer. In this respect, a dielectric material layer, which is thinner compared with the stop layer, can be placed between the first stop layer and the monocrystalline semiconductor region.

“Subsequent” is understood hereinafter to mean that these one or more “subsequent” process steps occur later in time in the overall manufacturing process. In this respect, no direct linking of the process steps is necessary, but additional process steps, such as, for example, cleaning steps, can be inserted before the process steps that follow.

The nature of the invention in this respect is the combination of the process steps described hereinafter. In so doing, it is provided first that for planarization a second stop layer is applied to the dielectric and subsequently a planarization layer, which in the area of each elevation forms a smaller layer thickness than outside the area of each elevation, is applied to the second stop layer. For example, the layer thickness of the planarization layer can vary by half.

Again subsequent to these process steps, the planarization layer in the area of each elevation and the second stop layer in the area of each elevation are removed. To remove the second stop layer, the layer can be etched, for example, by exposing the material of the second stop layer to an etchant, which results in a lower etching rate with respect to the second stop layer, compared with the planarization layer.

Again subsequently, the wafer is polished chemically-mechanically in such a way that the dielectric in the area of each elevation is made thinner up to the first stop layer. Outside the area of each elevation, the dielectric in contrast is not or only made slightly thinner. The first stop layer and the second stop layer therefore act as polishing stops, which significantly reduces the removal of the surface material by the chemical mechanical polishing.

A further embodiment of the invention provides that the planarization layer remaining outside the area of each elevation is removed before the chemical-mechanical polishing (CMP). For this purpose, the remaining planarization layer can be etched, for example, with an etchant acting selectively on the dielectric and the stop layer.

The exposed first stop layer and/or the exposed second stop layer can be removed after the chemical mechanical polishing (CMP).

Another embodiment of the invention provides that the planarization layer can be removed in the area of each elevation in such a way that outside the area of each elevation a residual planarization layer with such a thickness remains that etching of the second stop layer, covered by the planarization layer, does not occur or occurs only insignificantly. At least the function of the second stop layer as a polishing stop for the chemical mechanical polishing remains assured.

In a further embodiment, the dielectric, the first stop layer, and the second stop layer are applied in such a way that a parallel displacement of the similarly oriented surfaces of the first stop layer and the second stop layer is smaller than a thickness of the first stop layer and/or than a thickness of the second stop layer. Therefore, the application of the dielectric can be designed to be closely tolerant to the thickness of the monocrystalline semiconductor regions.

According to an another embodiment of the invention, to remove the planarization layer in the area of each elevation the planarization layer is etched. The etching occurs preferably thereby as a function of a time measurement.

Furthermore, the first stop layer and/or the second stop layer can have silicon nitride (Si₃N₄), which has a lower removal value in regard to the chemical-mechanical polishing than, for example, the silicon dioxide of the dielectric.

To achieve the desired planarization effects by the planarization layer, advantageous embodiments of the invention provide that the planarization layer has a photoresist or a polymer. Thereby, the planarization layer can also include several individual layers of the same or different materials, which intensify the planarization action during combined use. If, for example, a photoresist is used, it can be applied advantageously by spin coating.

Another aspect of the invention particularly with respect to a method for manufacturing integrated circuits having silicon-germanium heterobipolar transistors is provided as the modularization of the manufacturing process. The manufacturing process is divided into several process modules. A process module hereby, however, preferably has at least two process steps of the manufacturing process. For the division, according to the invention several or all process steps are combined into modules.

Defined as process modules are: a connection module to create a buried connection region; a collector/emitter module to create a collector region, adjacent to the connection region, and/or an emitter region, adjacent to the connection region; and a base module to create a base region.

A buried connection region is can be a conductive region, which is arranged relative to the wafer surface at least partially below an active semiconductor region particularly of the heterobipolar transistor. The active semiconductor region can be at least partially monocrystalline. The semiconductor region of the base is preferably directly adjacent to the collector region and/or the emitter region, which is made monocrystalline at least at the interface.

The nature of this aspect of the invention thereby is the development of a technology version, which is different from the existing technology version, in that the process modules have such process interfaces relative to one another that at least one process step of a process module with maintenance of the process interface is changed independent of the process steps of the other process modules for the different technology version.

The process interfaces preferably have one or more process conditions, which relate to the processes of at least two modules. For example, a high-temperature epitaxy process step in the collector/emitter module relates to both the diffusion and thereby the dopant distribution of the dopants, introduced in the connection module, and also the diffusion and thereby the dopant distribution of the dopants, introduced in the collector/emitter module, the dopant diffusing during the high-temperature epitaxy process step.

Technology versions differ when the electrical properties of at least one integrated component change with the change in technology. Preferably, the heterobipolar transistor is adapted to the desired specifications with the new technology version.

The creation of the preferably high-doped, metallic, and/or silicided leads for the aforementioned regions can thereby be a component of the specific process module and/or form one or more separate process modules.

According to a further embodiment of the invention, at least one process module has at least two module variants. The module variants thereby are used in one and the same technology version to create different components with a reduced number of necessary process steps. Preferably, the at least two module variants are carried out in the same integrated circuit. For example, a first module variant can be designed to create a collector region and a second module variant for the at least partial parallel creation of an emitter region.

Another embodiment of the invention provides that a first interface of the process interfaces is placed between the connection module and collector/emitter module in a sequence of the process steps before an epitaxial application of semiconductor material of the collector region and/or the emitter region.

Further, one of the process interfaces can be placed between the collector/emitter module and base module in a sequence of the process steps after the planarization of the dielectric. This can be, for example, a second process interface to the aforementioned interface, so that the manufacturing process has at least three process modules.

Another aspect of the invention is a use of the previously described manufacturing process for a semiconductor array to adapt the technology version to an application-specific boundary condition. Similarly, an aspect of the invention is the use of the method for manufacturing an integrated high-frequency circuit having at least one silicon-germanium heterobipolar transistor.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates process modules with assigned process interfaces,

FIG. 2a illustrates a first schematic sectional view after the process steps of the manufacture of a semiconductor array,

FIG. 2b illustrates a second schematic sectional view after the process steps of the manufacture of a semiconductor array,

FIG. 2c illustrates a third schematic sectional view after the process steps of the manufacture of a semiconductor array,

FIG. 2d illustrates a fourth schematic sectional view after the process steps of the manufacture of a semiconductor array

FIG. 2e illustrates a fifth schematic sectional view after the process steps of the manufacture of a semiconductor array.

### DETAILED DESCRIPTION

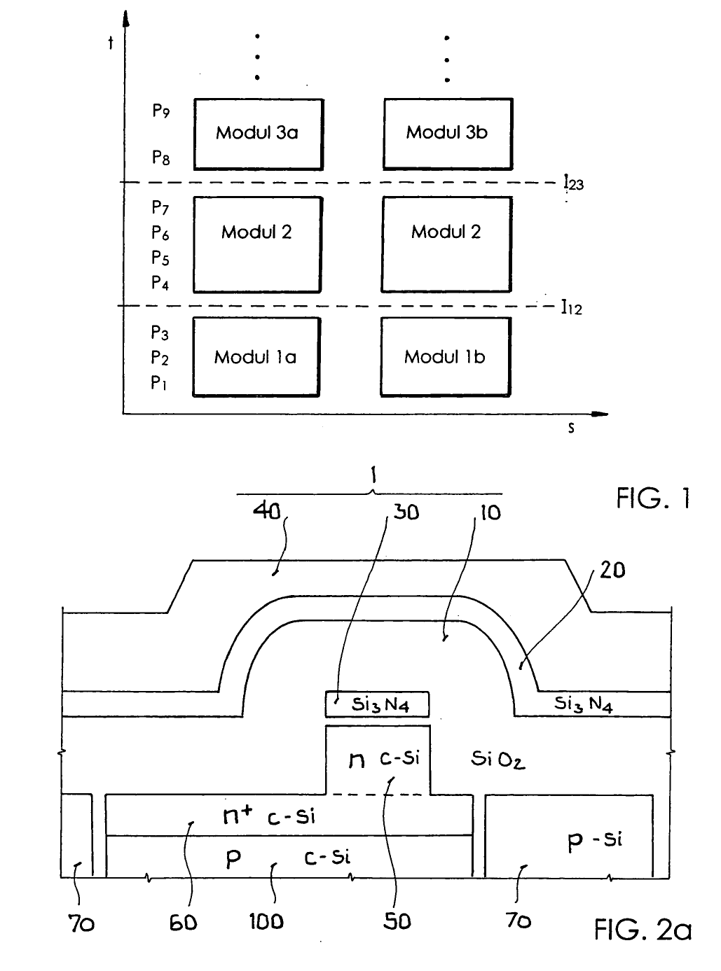

According to FIG. 1, the manufacturing process for a semiconductor array having a silicon-germanium heterobipolar transistor is divided into several process modules: module 1a, module 1b, module 2, module 3a, and module 3b. In this respect, the module division in the exemplary embodiment of FIG. 1 shows a first module variant module 1a for the first module (module 1a/module 1b) and a second module variant module 1b, as well as the module variants module 3a and module 3b for the third module.

The exemplary embodiment of FIG. 1 shows by way of example the advantageous division into three process modules, it being possible to combine both module variant 1a with module 2 and module variant 3a, module variant 1a with module 2 and module variant 3b, module variant 1b with module 2 and module variant 3a, and module variant 1b with module 2 and module variant 3b, in order to create transistors having different electrical properties on a semiconductor chip. The first module (module 1a, module 1b), the second module 2, and the third module (module 3a, 3b) according to the exemplary embodiment of FIG. 1 follow one after another in time t.

The modules, module 1a, module 1b, module 2, module 3a, and module 3b, each have one or several process steps, P1 to P3, P4 to P7, or P8 to P9, respectively, of the manufacturing process, which are also identical for the different module variants. Variants of the modules can be produced, for example, by appropriate masking and thereby by a lateral offset “s” on the wafer.

The modules, module 1a, module 1b, module 2, module 3a, and module 3b, are thereby defined relative to each other by process interfaces I₁₂, I₂₃. In the exemplary embodiment of FIG. 1, the process interfaces I₁₂, I₂₃ are arranged in time between the first module, module 1a, module 1b, and the second module, module 2, and between the second module, module 2, and the third module, module 3a and module 3b. An interface, not shown in FIG. 1, between the first module, module 1a, module 1b, and the third module, module 3a, module 3b, is also possible.

The invention is thereby not limited to the exemplary embodiment depicted in FIG. 1. It is possible to add additional modules and interfaces by suitable definition. Additional modules are indicated in FIG. 1 by dots.

For example, module 1 is a buried connection region for the electrical contacting of a collector semiconductor region or an emitter semiconductor region of the heterobipolar transistor. Module variant 1a, in comparison with module variant 1b, has a lower dopant concentration or a different dopant, so that the thermal budget defined in the subsequent modules 2 and 3 leads to different diffusion of the dopant, introduced into module 1, into semiconductor layers arranged above during modules 2 and 3.

If this semiconductor layer is, for example, an active collector semiconductor layer, both module variants 1a and 1b accordingly produce different collector drift zones for heterobipolar transistors with different high-frequency properties. Furthermore, the module variants 3a and 3b can create, for example, different base regions.

If proceeding from process steps P1 to P9, assigned to the modules, a new technology generation with new heterobipolar transistors with, for example, a higher breakdown voltage stability is desired, in this case only process steps P4 to P7 of module 2 are changed. The other process steps, P1 to P3 and P8 to P9, remain unchanged. The options for changing process steps P4 to P7 of module 2 are thereby limited by the defined interfaces I₁₂ and I₂₃. In other words, the interface-defined boundary conditions for process steps P4 to P7 remain unchanged.

For example, module 1 according to the process interface I₁₂ requires a certain thermal budget due to the following module 2. If process steps P4 to P7 for the new technology version in new process steps (P4′ to P7′, not shown in FIG. 1) are changed, maintenance of the thermal budget is absolutely necessary. If the thermal budget, for example, is too low, a thermal replacement process must be added, which is used exclusively to maintain the process interface condition.

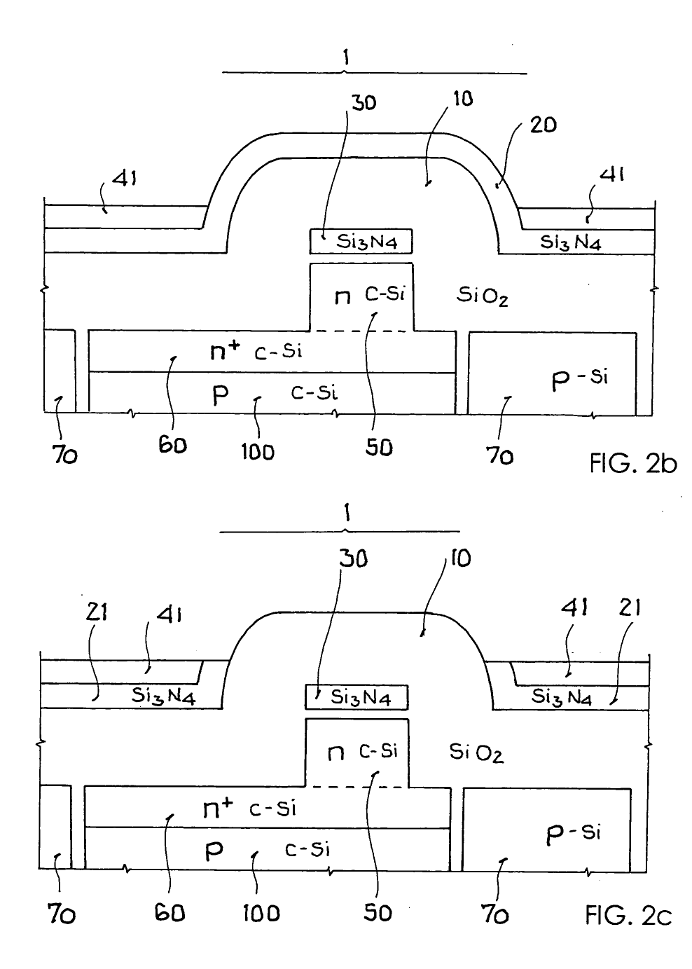

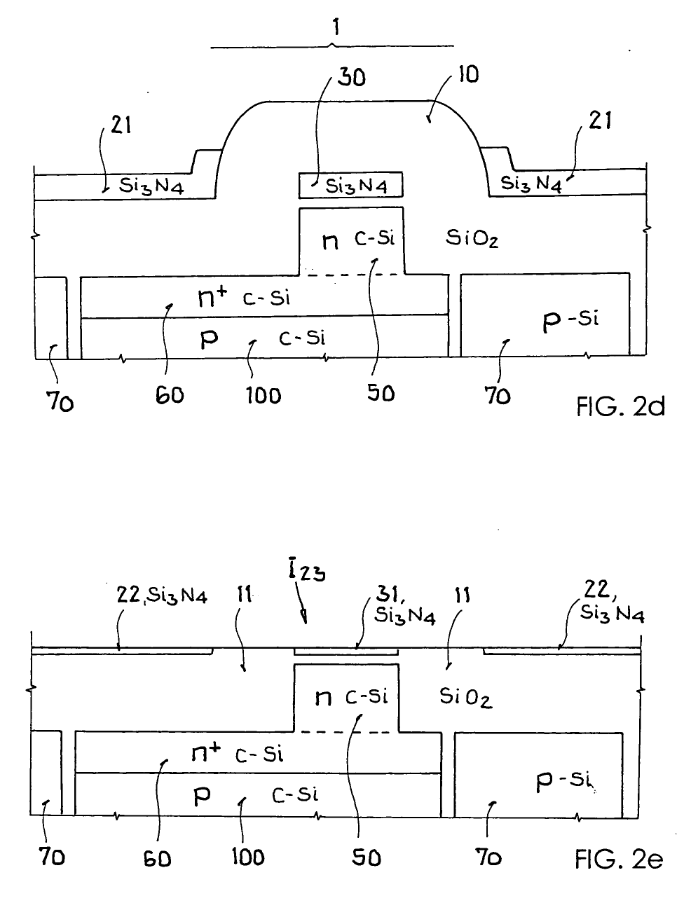

In FIGS. 2a to 2e processes of the second module are shown, which define a structural condition of a process interface I₂₃. This therefore adds the boundary condition that for process steps of the subsequent module, the geometric interface, shown schematically in FIG. 2d, is to be assumed.

Sectional views of a segment of a processed wafer after certain process steps are shown in FIGS. 2a to 2e. The process steps are used thereby to create a substantially planar surface without elevations, which could influence the later process steps.

A portion of a monocrystalline, p-doped silicon substrate 100 is shown, on which a high-doped, buried layer 60 of the n-conductivity type is deposited epitaxially. A heterobipolar transistor is to be produced in a region of the buried layer 60 in the following process steps—not all of which are shown in FIGS. 2a to 2e. To isolate this heterobipolar transistor from other transistors or other components, trench isolations are provided, which are filled with a polycrystalline silicon 70.

A monocrystalline collector semiconductor region 50, which has a lower dopant concentration than the buried layer 60, is applied epitaxially to the buried layer 60. A first stop layer 30 of silicon nitride, which may be separated from the collector semiconductor region 50 by a thin silicon dioxide layer, is applied to the semiconductor region 50.

A dielectric 10 of silicon dioxide, which has a thickness dependent on the collector semiconductor region 50, is applied over the surface structure, which comprises the buried layer 60, the collector semiconductor region 50, and the first stop layer 30. Preferably, the collector semiconductor region 50 and the dielectric 10 have the same thickness within the scope of production tolerances.

The nonplanar surface, determined by the built-up height of the collector semiconductor region 50 and the first stop layer 30, upon application of the dielectric 10 over the entire wafer surface, has the effect that in the area of the collector semiconductor region 50 an elevation 1 within the surface of dielectric 10 is formed, which can negatively affect or prevent the following process steps for creating the base (not shown).

To obtain a planar surface as a starting point for the additional process steps, the following process steps, partially depicted in FIGS. 2a to 2e, are carried out one after another. In addition to the process steps described hereinafter, additional process steps, such as cleaning steps, etc., may be necessary in terms of process technology, which are omitted in this explanation for the purpose of simplification.

First, a second stop layer 20 is applied over the entire wafer surface. On this stop layer 20, a photoresist 40, acting as a planarization layer, is spin coated onto the entire stop layer area, so that in the area of the elevations 1 the photoresist 40 has a lower thickness than outside the area of the elevations 1.

The state after the applied photoresist 40 of FIG. 2a has been etched for a time is shown in FIG. 2b. The etching time thereby is selected such that outside the area of the elevation 1 a residual resist layer 41 remains, which covers the second stop layer 20 in the area outside elevation 1. Here, the remaining thickness of the residual resist layer 41 is sufficiently large, so that, as depicted in FIG. 2c, the second stop layer 20 of FIG. 2b is etched exclusively in the area of the elevation 1. Accordingly, after the etching the unetched second stop layer 21 remains underneath the residual resist layer 41.

Before a chemical mechanical polishing (CMP) of the surface of the wafer, the residual resist layer 41 is removed as depicted in FIG. 2d. The first stop layer 30 disposed within elevation 1 and the second stop layer 21, now covering the surface of the wafer outside elevation 1, remain; both act as a polishing stop.

FIG. 2e shows the state of the wafer segment after the chemical-mechanical polishing (CMP). The wafer has a planar surface. Elevation 1 of the preceding figures has been removed. A first residual stop layer 31 and a second residual stop layer 22 remain, which can be removed for subsequent processes. Furthermore, two dielectric regions 11 have formed.

The obtained planar surface of the wafer is preferably a process interface condition of a second process interface I₂₃, previously explained with respect to FIG. 1. Additional process interface conditions are, for example, the dopant concentration or the lattice defects at the boundary of the collector semiconductor region 50.

The advantages of the exemplary embodiments in FIGS. 2a to 2e are that by the application of the second stop layer, no further structuring effort arises during the manufacturing process. Irregularities of the chemical mechanical polishing are reduced. The uniformity of the entire process sequence in the exemplary embodiment of FIGS. 2a to 2e corresponds substantially only to the uniformity of the dielectric formation. For this reason, minor tolerances in the process result of the entire process chain can be achieved in the depicted collector module. As a result, the manufacture of smaller structures is possible in particular.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for manufacturing integrated circuits having at least one silicon-germanium heterobipolar transistor, the method comprising the steps of:
planarizing a dielectric that is applied to a surface of a wafer, the dielectric having elevations produced by a thickness of monocrystalline semiconductor regions structured below the dielectric, the semiconductor regions being covered by a first stop layer, in that for the purpose of planarization
applying a second stop layer the dielectric;
applying to the second stop layer, a planarization layer, which in an area of each elevation forms a smaller layer thickness than outside an area of each elevation;
removing the planarization layer in the area of each elevation;
removing the second stop layer in the area of each elevation; and
chemically-mechanically polishing the wafer so that the dielectric in the area of each elevation is made thinner at least up to the first stop layer.

2. The method according to claim 1, wherein the planarization layer remaining outside the area of each elevation is removed before the chemical-mechanical polishing.

3. The method according to claim 1, wherein the exposed first stop layer and/or the exposed second stop layer are removed after the chemical-mechanical polishing.

4. The method according to claim 1, wherein the planarization layer is removed in the area of each elevation in such a way that outside the area of each elevation a residual planarization layer with a thickness remains that etching of the second stop layer, covered by the planarization layer, does not occur or occurs only insignificantly.

5. The method according to claim 1, wherein the dielectric, the first stop layer, and the second stop layer are applied in such a way that a parallel displacement of the similarly oriented surfaces of the first stop layer and the second stop layer is smaller than a thickness of the first stop layer and/or than a thickness of the second stop layer.

6. The method according to claim 1, wherein to remove the planarization layer in the area of each elevation, the planarization layer is etched as a function of a time measurement.

7. The method according to claim 1, wherein the first stop layer and/or the second stop layer has silicon nitride (Si₃N₄).

8. The method according to claim 1, wherein the planarization layer has a photoresist or a polymer.

9. The method according to claim 1, wherein the manufacturing process is divided into a plurality of process modules, the process modules including:
a connection module to create a buried connection region;
a collector/emitter module to create a collector region adjacent to the connection region, and/or an emitter region adjacent to the connection region; and
a base module to create a base region
wherein the connection module, the collector/emitter module, and the base module are the process modules, and
wherein the process modules have such process interfaces relative to one another that to develop the technology version different from existing technology version, at least one process step of a process module with maintenance of the process interface is changed independent of the process steps of the other process modules.

10. The method according to claim 9, wherein one of the process interfaces is placed between the collector/emitter module and base module in a sequence of the process steps after the planarization of the dielectric.

11. Use of a method for manufacturing integrated circuits according to claim 9 to adapt the technology version to an application-specific boundary condition.

12. The method according to claim 1, wherein the integrated circuits are integrated high-frequency circuits having at least one silicon-germanium heterobipolar transistor.
